(19) United States
(12) Patent Application Publication
(10) Pub. No.: US 2011/0199720 A1
(43) Pub. Date: Aug. 18, 2011

(54) LID SEALING STRUCTURE, AND ELECTRONIC DEVICE EQUIPPED WITH SAME

(75) Inventors: Kenichi KAJIYAMA, Hyogo (JP); Yuji Tominaga, Osaka (JP); Tomoki Sakamoto, Osaka (JP)

(73) Assignee: Panasonic Corporation, Osaka (JP)

(21) Appl. No.: 13/024,332

(22) Filed: Feb. 10, 2011

(30) Foreign Application Priority Data
Feb. 17, 2010 (JP) 2010-032200

(51) Int. Cl. H05K 5/03; B65D 53/06; B65D 43/16

(52) U.S. Cl. 361/679.01; 220/849

(57) ABSTRACT

A lid sealing structure is provided that includes a housing, a lid, and a waterproof gasket. The housing defines an interior space with an opening and includes a sealing portion that encircles the opening and provides access to the interior space. The lid is configured to cover and uncover the opening. The waterproof gasket includes a base portion, a first contact portion, and a second contact portion. The base portion is mounted to the lid, and the first and second contact portions extend from the base portion and arranged to contact the sealing portion.

### CROSS-REFERENCE TO RELATED APPLICATIONS

This application claims priority under 35 U.S.C. §119 to Japanese Patent Application No. 2010-032200, filed on Feb. 17, 2010. The entire disclosures of Japanese Patent Applications No. 2010-032200 is hereby incorporated herein by reference.

### BACKGROUND

1. Technical Field

The technology disclosed herein relates to a lid sealing structure.

2. Background Information

Electronic devices having a water-resistant feature, and electronic devices that can be used in water often make use of a lid structure for preventing water from penetrating into the holding component in which a battery or the like is held, on the lid that blocks off the holding component. Also, in addition to batteries, a memory card or other such storage medium is often held in the holding component.

Preventing the invasion of water into the holding component is critical with an electronic device such as this. Not only would such invasion short out the battery, but it could also lead to the loss of or damage to important data if the electronic device is one that produces, edits, records, or otherwise handles data.

Further, recent years have seen digital cameras come onto the market which can be used in the ocean at depths of from a few meters or about 10 meters, even though the case is not equipped with any waterproofing function such as a marine case. With a digital camera such as this, a lid structure with an improved waterproof function is needed to maintain the waterproof function against high water pressure. Also, when a marine case or other such outer casing is used on an electronic device not equipped with a waterproof function, a relatively good waterproof function is needed for the outer casing just as above.

With the lid sealing structure described in Japanese Laid-Open Patent Application JP2003-142841, the battery compartment is sealed by bringing a waterproof gasket, which is mounted around the outer periphery of a waterproof gasket seat, into snug contact with the inclined face of the opening part of the battery compartment.

With the battery lid structure described in JP 2003-142841, however, since the waterproof gasket only comes into direct contact at one place on the inclined face of the opening part of the battery compartment, it is difficult to maintain the sealed state of the battery compartment if hair, sand, or other foreign matter should become stuck between the waterproof gasket and the inclined face of the opening to the battery compartment.

### SUMMARY

One object of the invention to provide a lid sealing structure whereby the sealing performance can be improved.

In accordance with one aspect of the invention, a lid sealing structure is provided that includes a housing, a lid, and a waterproof gasket. The housing defines an interior space with an opening and includes a sealing portion that encircles the opening and provides access the interior space. The lid is configured to cover and uncover the opening. The waterproof gasket includes a base portion, a first contact portion, and a second contact portion. The base portion is mounted to the lid, and the first and second contact portions extend from the base portion and arranged to contact the sealing portion.

These and other objects, features, aspects and advantages of the present invention will become apparent to those skilled in the art from the following detailed description, which, taken in conjunction with the annexed drawings, discloses embodiments of the present invention.

### BRIEF DESCRIPTION OF DRAWINGS

Referring now to the attached drawings which form a part of this original disclosure:

FIG. 1A is a rear view of a digital camera, FIG. 1B is a front view of a digital camera, and FIG. 1C is a bottom view of a digital camera;

FIGS. 2A to 2D are diagrams illustrating the opening and closing operation of the lid;

FIG. 3A is a bottom view of a digital camera (corresponds to FIG. 2A when the lid is closed), and FIG. 3B is a bottom view of a digital camera corresponds to FIG. 2D when the lid is open);

FIG. 4 is an oblique view of a waterproof gasket;

FIG. 5 is a cross section of a lid and a lid locking mechanism;

FIG. 6A is a detail enlargement of FIG. 5, and FIG. 6B is a detail enlargement of FIG. 5;

FIG. 7 is a VII-VII cross section of FIG. 3A;

FIG. 8A is a detail enlargement of FIG. 7, and FIG. 8B is a detail enlargement of FIG. 7; and

FIG. 9A is a detail enlargement of the sealing portion and waterproof gasket corresponding to FIG. 8A (just before the lid is closed), and FIG. 9B is a detail enlargement of the sealing portion and waterproof gasket corresponding to FIG. 8B (just before the lid is closed).

### DETAILED DESCRIPTION OF EMBODIMENTS

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

Configuration of Digital Camera

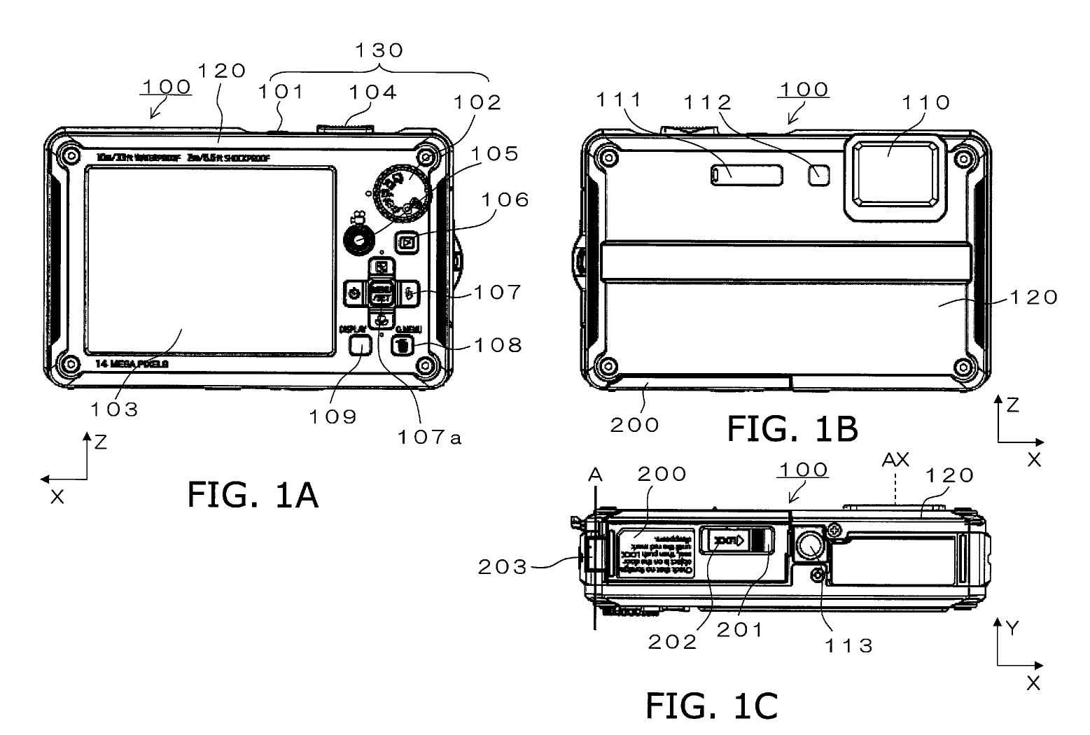

A digital camera 100 pertaining to a first embodiment will be described through reference to FIGS. 1A to 4C. To facilitate the description, a three-dimensionally perpendicular coordinate system is set up for the digital camera 100. The X axis is set parallel to the left and right direction when the digital camera 100 is used. The Y axis is set parallel to the optical axis AX of the digital camera 100. The Z axis is set parallel to the up and down direction (vertical direction) when the digital camera 100 is used. In the following description, the X axis direction shall be a direction parallel to the X axis, and is an example of a first direction. The Y axis direction shall be a direction parallel to the Y axis. The Z axis direction shall be a direction parallel to the Z axis. The left side facing the subject shall be termed the X axis direction positive side. The subject side in the Y axis direction shall be termed the Y axis direction positive side. The upper side along the Z axis direction shall be termed the Z axis direction positive side.

The vertically upper side (Z axis direction positive side) in the normal orientation of the digital camera 100 (hereinafter also referred to as the landscape orientation) is also called the top, and the vertically lower side (Z axis direction negative side) the bottom, but these expressions do not serve to limit the usage state of the digital camera 100.

As shown in FIGS. 1A to 1C, the digital camera 100 (an example of an electronic device) comprises an optical system 110, a strobe 111, a manipulation unit 130, a body 120 (an example of a housing), a lid 200 (an example of a lid), a lid locking mechanism 140, and a waterproof gasket 204 (an example of a waterproof gasket).

As shown in FIG. 1B, the optical system 110 is disposed on the front face of the digital camera 100, and leads light to an imaging element (not shown). The optical system 110 has an optical axis AX. The strobe 111 is provided to the front face of the digital camera 100 to make imaging possible in dark locations. For example, the digital camera 100 employs an auto-focus function that automatically adjusts the focus on a particular subject. An AF auxiliary light generator 112 is provided so that the auto-focus function can operate properly even in dark locations.

As shown in FIG. 1A, the manipulation unit 130 has a power button 101, a mode dial 102, a liquid crystal monitor 103, a shutter button 104, a moving picture button 105, a reproduction button 106, a cross key 107, quick menu button 108, and a display button 109. The manipulation unit 130 is provided on the front and rear faces of the body 120.

When the power button 101 is pressed, power is supplied to the digital camera 100. The desired imaging mode can be selected by turning the mode dial 102. Since the subject is displayed on the liquid crystal monitor 103, the user can compose a picture while looking at the subject displayed on the liquid crystal monitor 103. When the shutter button 104 is pressed, a still picture can be captured. When the moving picture button 105 is pressed, a moving picture can be captured. When the reproduction button 106 is pressed, a captured still or moving picture can be reproduced on the liquid crystal monitor 103.

When the cross key 107 is pressed, various settings can be made for imaging or reproduction. In addition to showing directions, the various buttons that make up the cross key 107 may also be assigned individual functions. For instance, in addition to showing the upward direction, the up button of the cross key 107 may also be assigned the function of exposure correction. Also, a menu button 107a is provided in the center of the cross key 107. When this menu button 107a is pressed, a setting menu screen is displayed on the liquid crystal monitor 103.

When the quick menu button 108 is pressed, some of the settings can be easily changed. The quick menu button 108 also functions as a delete button for deleting captured still or moving pictures.

When the display button 109 is pressed, the information displayed on the liquid crystal monitor 103 is switched. Imaging information, guidelines that assist in composing a picture, and so forth are displayed on the liquid crystal monitor 103.

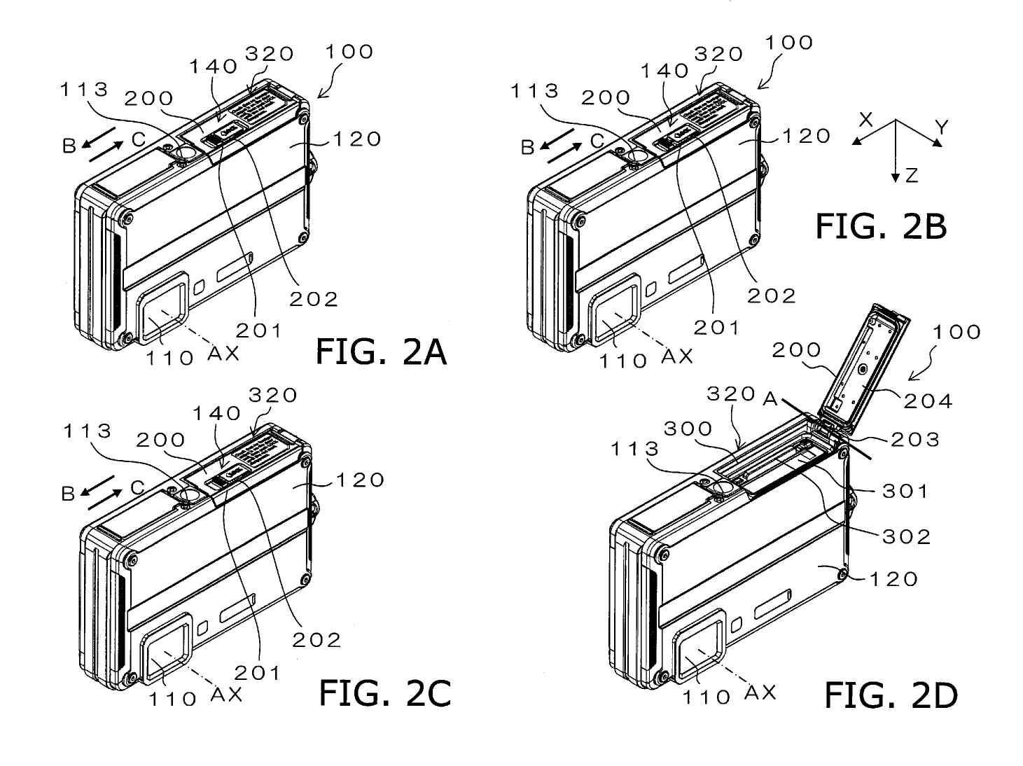

As shown in FIG. 2D, the body 120 includes the shell or frame of the digital camera 100, and has a holding unit 320. A battery 301 and a memory card 302 or other such accessories are removably held in the holding unit 320. The holding unit 320 has an opening 310 (an example of an opening) for putting in the battery 301 and the memory card 302. The opening 310 has a substantially rectangular shape that extends in the X axis direction, and is formed in the bottom face of the body 120. The lid 200 is linked to the body 120 so that the opening 310 can be opened and closed.

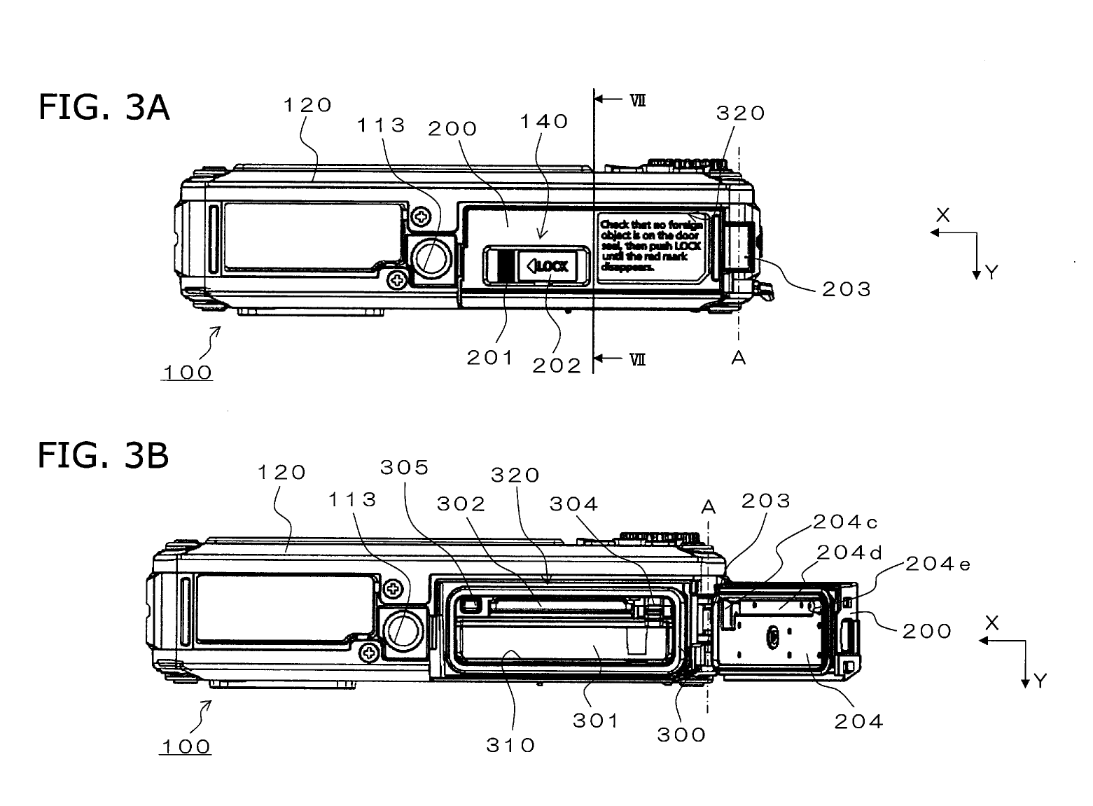

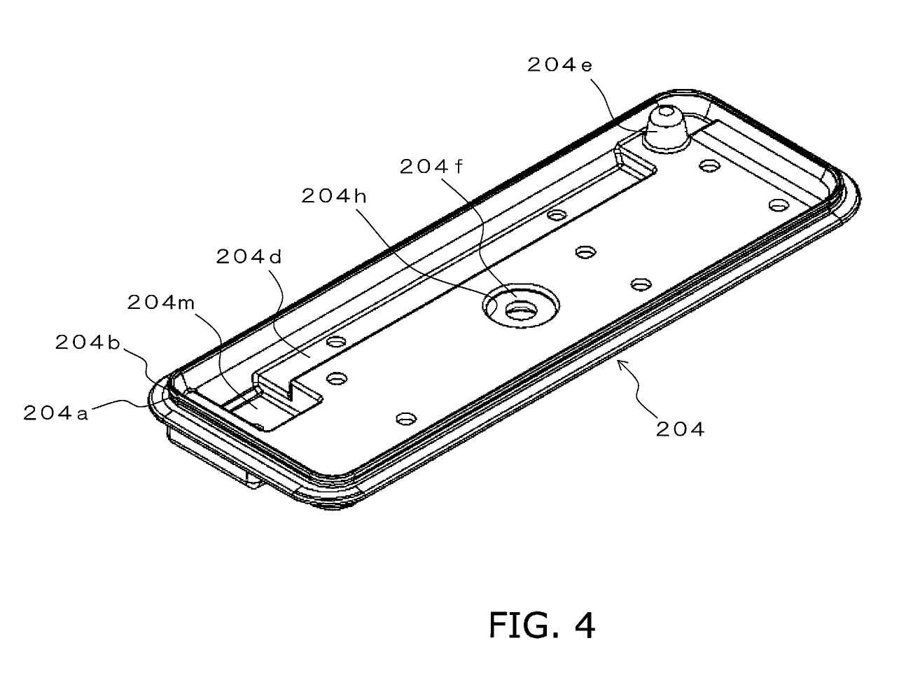

The holding unit 320 has a battery lock 304 so that the battery 301 will not fall out when the lid 200 is opened. When the battery lock 304 is slid upward in FIG. 3B, the battery 301 is unlocked, allowing the battery 301 to be removed. A recess 204m is provided to the waterproof gasket 204 so that the battery lock 304 will not touch the waterproof gasket 204 when the lid 200 is open (see FIG. 4).

A so-called push-push type of connector is employed for the holding unit 320 in order to attach the memory card 302 to the 100. Accordingly, to attach or remove the memory card 302, the memory card 302 must be pushed in by a specific amount inward toward the center in FIG. 3B. Therefore, the top of the memory card 302 sticks out slightly towards the viewer in FIG. 3B. A recess 204d is provided to the waterproof gasket 204 so that the top of the memory card 302 will not hit the waterproof gasket 204 when the lid 200 is in a closed state (see FIG. 4).

As shown in FIG. 3B, the holding unit 320 has a substantially annular sealing portion 300 disposed around the peripheral edge of the opening 310. The term “substantially annular” here refers to a shape that is formed continuously all the way around, without any gaps. Therefore, “substantially annular” also encompasses a quadrilateral shape such as that of the sealing portion 300. The waterproof gasket 204 is in contact with the sealing portion 300 when the lid 200 is in the closed state. The sealing portion 300 forms the opening 310. The sealing portion 300 will be described in detail below.

As shown in FIGS. 2D, 3A, and 3B, an attachment screw hole 113 for fixing the digital camera 100 to a tripod or monopod is provided to the bottom face of the body 120. The lid 200 is mounted to the bottom face of the body 120 to open and close the opening 310.

A hinge 203 is provided to the edge of the opening 310, and the lid 200 is, for example, pivotally coupled by the hinge 203 to the body 120. The hinge 203 is disposed at the corner on the bottom face side of the digital camera 100. Since the opening 310 is longer in the X axis direction, the lid 200 also has a substantially rectangular shape that is longer in the X axis direction. In this embodiment, the lid 200 rotates around a rotational axis A, but does not slide in the X axis direction with respect to the body 120. Also, in this embodiment, no coil spring is provided to the hinge 203, and the lid 200 does not open automatically. Instead, as shown in FIGS. 2A to 2D, the lid 200 is easy to open by hard since part of the lid shell 200a can be seen from the front face of the digital camera 100.

However, a coil spring may be provided to the hinge 203 so that the lid 200 will open automatically. In this case, when a first lock lever 201 is slid in a C direction, the locking provided by a lock pawl 201a and a protrusion 303 is released, and the lid 200 opens automatically under the elastic force of the coil spring.

When the lid 200 is opened, the battery 301 and the memory card 302 held in the holding unit 320 can be seen. The battery 301 and the memory card 302 can be installed in or removed from the holding unit 320 as needed.

The lid 200 has a plastic lid shell 200a and a metal reinforcing plate 200b that reinforces the lid shell 200a. The lid shell 200a constitutes the shell of the digital camera 100 along with the body 120. The reinforcing plate 200b is mounted to the rear side of the lid shell 200a, and is disposed between the lid shell 200a and the waterproof gasket 204. The lid locking mechanism 140 is provided to the lid 200 to lock the lid 200 in the closed state.

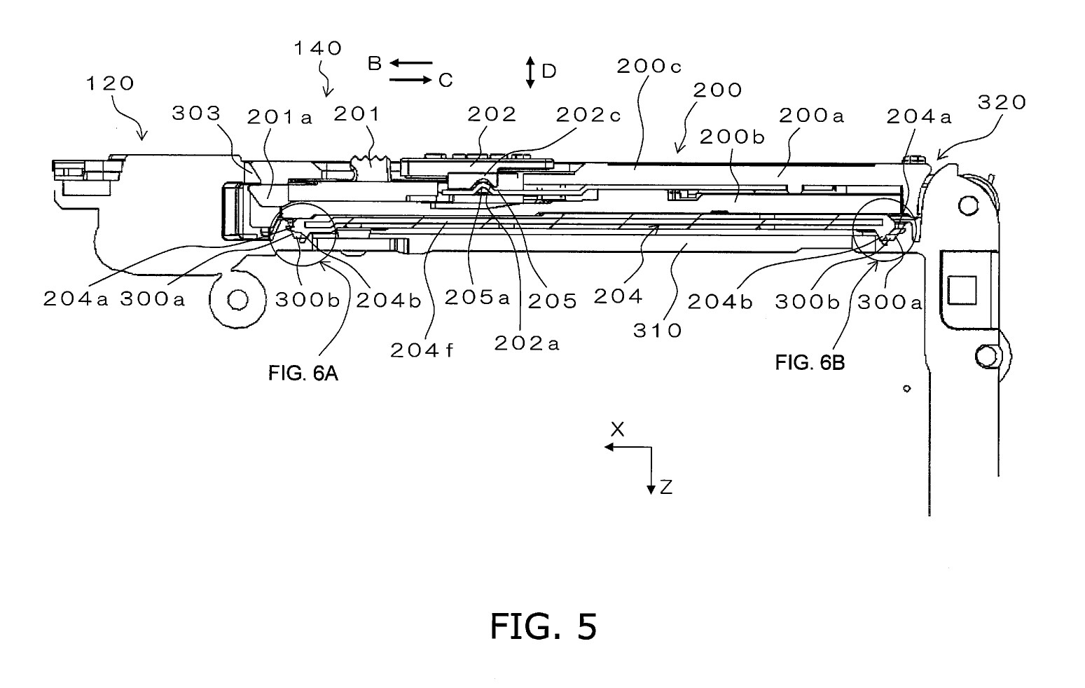

As shown in FIG. 5, the lid locking mechanism 140 has the first lock lever 201, a leaf spring 205, and a second lock lever 202.

The first lock lever 201 is provided to lock the lid 200 in a closed state, and is supported by the lid 200 movably in the X axis direction. The first lock lever 201 so as to be able to come into contact with the leaf spring 205. As shown in FIG. 3, the first lock lever 201 has the lock pawl 201a. The body 120 has the protrusion 303, which is provided so as to be able to come into contact with the lock pawl 201a. When the first lock lever 201 is disposed in a closed position, the lock pawl 201a hooks onto the hinge 203. When the first lock lever 201 is disposed in an open position, the lock pawl 201a does not hook onto the hinge 203.

The leaf spring 205 is provided to restrict the first lock lever 201 from moving to the open position, and is mounted to the lid 200 so as to be capable of elastic deformation in the Z axis direction. The leaf spring 205 extends in a slender shape in the X axis direction, and is disposed along the rear face of the lid 200. The direction in which the leaf spring 205 extends coincides with the lengthwise direction of the digital camera 100. The leaf spring 205 is made of metal, for example.

The leaf spring 205 is disposed movably between a restricting position at which movement of the first lock lever 201 to the open position is restricted, and a retracted position at which movement of the first lock lever 201 to the open position is permitted. Switching the leaf spring 205 between the restricting position and the retracted position is performed by the second lock lever 202.

The leaf spring 205 has a convex portion 205a. The convex portion 205a protrudes to the second lock lever 202 side, and is formed by bending the leaf spring 205. When the leaf spring 205 is guided by the second lock lever 202, the convex portion 205a slides with a guide portion 202c of the second lock lever 202. The convex portion 205a restricts the movement of the second lock lever 202 in the X axis direction.

The second lock lever 202 is provided to lock the first lock lever 201 in the closed position, and is supported by the lid 200 movably in the X axis direction. The second lock lever 202 is disposed so that the position of the leaf spring 205 can be switched between the restricting position and the retracted position.

The second lock lever 202 has the guide portion 202c. The guide portion 202c protrudes from the lever main body 202b toward the leaf spring 205, and is provided slidably with the leaf spring 205. The guide portion 202c guides the leaf spring 205 between the restricting position and the retracted position. More specifically, the guide portion 202c has a concave part 202a. When the second lock lever 202 is disposed at the locked position, the convex part 205a of the leaf spring 205 is fitted into the concave part 202a, and the leaf spring 205 is held at the restricting position. Since the convex part 205a is fitted into the concave part 202a, movement of the second lock lever 202 in the X axis direction is restricted by the convex part 205a. When the second lock lever 202 moves from the locked position to the unlocked position, the leaf spring 205 is guided from the restricting position P21 to the retracted position.

Configuration of Waterproof Gasket and Holding Component

As shown in FIG. 2D, the waterproof gasket 204 is provided to the rear face of the lid 200 to prevent liquids or dust from getting into the holding unit 320 through a gap formed between the lid 200 and the body 120. The sealing portion 300 and the waterproof gasket 204 will now be described in detail through reference to FIGS. 4 to 9B.

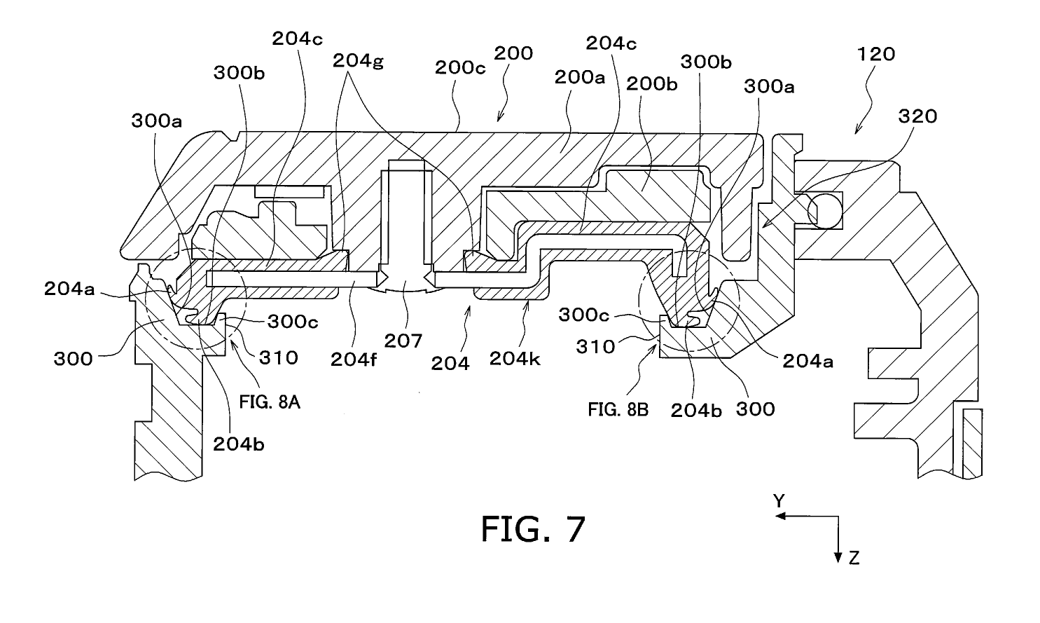

As shown in FIG. 7, the waterproof gasket 204 has a core 204f and a gasket body 204k. The core 204f is made of metal, and is fixed by a screw to the lid 200. Since the core 204f is made of metal, it can maintain the shape of the waterproof gasket 204 to a certain extent. Also, since the metal core 204f is fixed to the lid 200, the attachment strength of the waterproof gasket 204 can be increased. The core 204f is sealed inside the gasket body 204k.

The gasket body 204k is made of silicone rubber, and is entirely formed as a single piece. In addition to silicone rubber, examples of the material of the gasket body 204k include urethane rubber, nitrile rubber, and fluororubber.

As shown in FIG. 7, the gasket body 204k has a base portion 204c, a first contact portion 204a, and a second contact portion 204b. The base portion 204c covers the core 204f, and is mounted to the lid 200 via the core 204f.

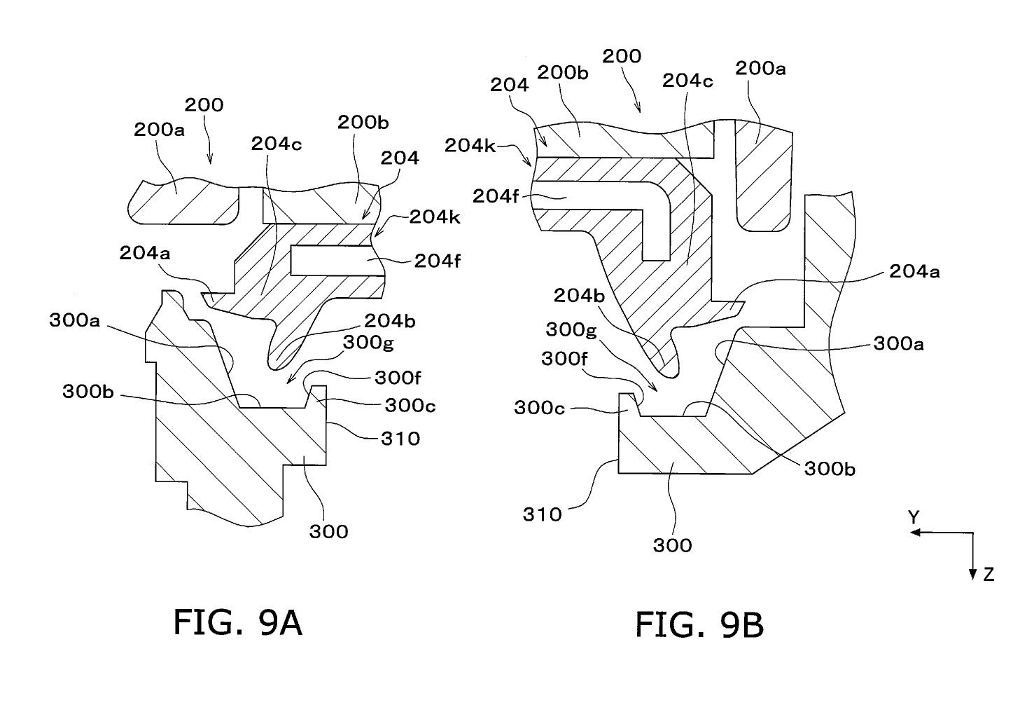

As shown in FIGS. 9A and 9B, the first contact portion 204a is a substantially annular portion provided so as to be able to come into contact with the sealing portion 300, and protrudes from the base portion 204c. The first contact portion 204a protrudes outward from the base portion 204c. More precisely, the first contact portion 204a protrudes outward from the base portion 204c, and the direction in which the first contact portion 204a protrudes is substantially parallel to the main face 200c of the lid 200.

As shown in FIGS. 9A and 9B, the second contact portion 204b is a substantially annular portion provided so as to be able to come into contact with the sealing portion 300, and protrudes from the base portion 204c. The direction in which the second contact portion 204b protrudes is different from the direction in which the first contact portion 204a protrudes. In this embodiment, the second contact portion 204b protrudes from the base portion 204c to the opposite side from the lid 200, and the direction in which the second contact portion 204b protrudes is inclined with respect to the main face 200c of the lid 200.

The sealing portion 300 of the body 120 is a substantially annular portion that forms the opening 310, and is disposed at a position where it can come into snug contact with the waterproof gasket 204. The sealing portion 300 is formed so as to surround the opening 310. The first contact portion 204a and second contact portion 204b of the waterproof gasket 204 are able to come into snug contact all the way around the periphery of the sealing portion 300. More specifically, the body 120 has a substantially annular first sealing face 300a and a substantially annular second sealing face 300b.

The first sealing face 300a is provided so as to be able to come into contact with the first contact portion 204a of the waterproof gasket 204. The first sealing face 300a is inclined with respect to the second sealing face 300b. More specifically, the first sealing face 300a is inclined so as to be closer to the second sealing face 300b as it approaches the opening 310. To put this another way, the first sealing face 300a is inclined with respect to the direction (D direction) in which the battery 301 and the memory card 302 are inserted. In this embodiment, the D direction is parallel to the Z axis direction. The first sealing face 300a is inclined so that the inside size of the sealing portion 300 gradually decreases toward the opening 310. Since the first sealing face 300a is inclined in this way, it is easier for the first contact portion 204a to come into snug contact with the first sealing face 300a in closing the lid 200. The first sealing face 300a may be parallel to the D direction.

The second sealing face 300b is provided so as to be able to come into contact with the second contact portion 204b of the waterproof gasket 204. The second sealing face 300b is disposed closer to the opening 310 than the first sealing face 300a. The second sealing face 300b is disposed substantially parallel to the main face 200c of the lid 200 when the lid 200 is in the closed state. Also, the second sealing face 300b is disposed substantially perpendicular to the D direction. Because the second sealing face 300b is substantially perpendicular to the D direction, the second sealing face 300b bears the pressing force when the lid 200 is closed. Therefore, the lid 200 can be prevented from being pressed in too far when the lid 200 is being closed.

Using the lid 200 as a reference, when the lid 200 is in the closed state, the inclination angle of the first sealing face 300a with respect to the main face 200c of the lid 200 is different from the inclination angle of the second sealing face 300b with respect to the main face 200c of the lid 200.

The state of the waterproof gasket 204 and the sealing portion 300 when the lid 200 is closed will now be described.

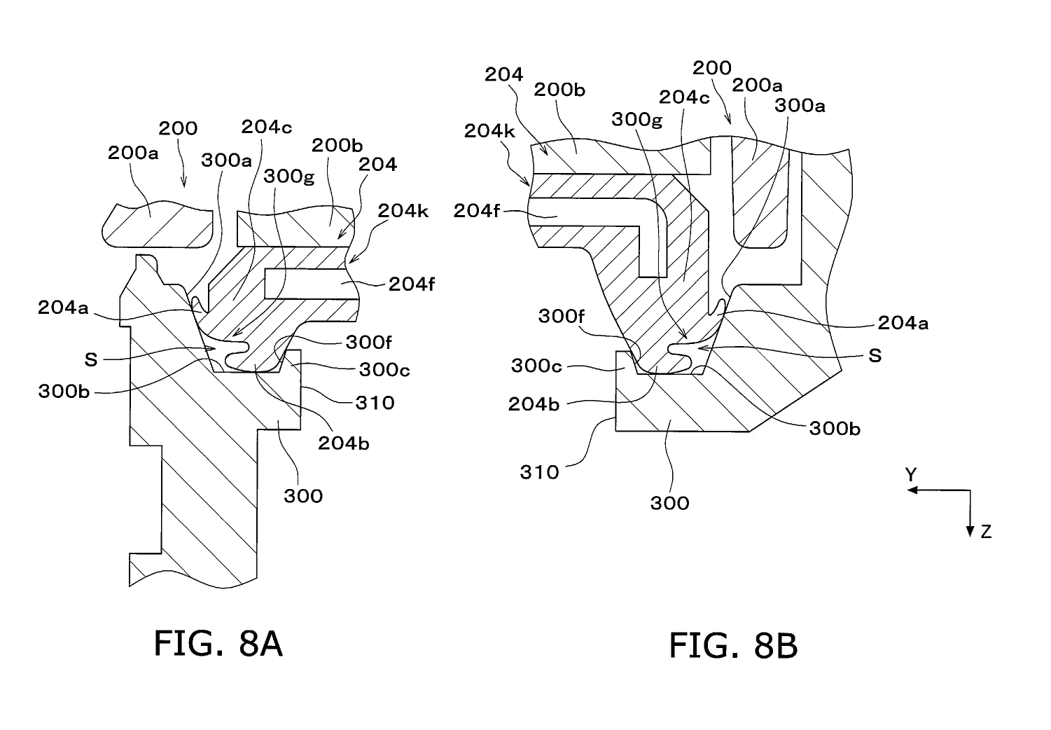

As shown in FIGS. 8A and 8B, when the lid 200 is in the closed state, the first contact portion 204a is in snug contact with the first sealing face 300a of the sealing portion 300. Since the first sealing face 300a is inclined, in a state in which the first contact portion 204a is pressed against the first sealing face 300a, the first contact portion 204a is elastically deformed so as to move away from the opening 310. In other words, in a state in which the first contact portion 204a is pressed against the first sealing face 300a, the first contact portion 204a is elastically deformed so as to move away from the second contact portion 204b.

As shown in FIGS. 8A and 8B, when the lid 200 is in the closed state, the second contact portion 204b is in snug contact with the second sealing face 300b of the sealing portion 300. The second contact portion 204b is disposed closer to the opening 310 than the first contact portion 204a when the lid 200 is in the closed state. In a state in which the second contact portion 204b is pressed against the second sealing face 300b, the second contact portion 204b is elastically deformed so as to move away from the opening 310. In other words, in a state in which the first contact portion 204a is pressed against the first sealing face 300a, the first contact portion 204a is elastically deformed so as to move closer to the first contact portion 204a. In a state in which the first contact portion 204a is in contact with the first sealing face 300a, and the second contact portion 204b is in contact with the second sealing face 300b, a space S is formed between the first contact portion 204a and the second contact portion 204b. Consequently, the first contact portion 204a and the second contact portion 204b do not interfere with each other during elastic deformation. Since the second contact portion 204b is pressed against the second sealing face 300b, the second contact portion 204b also serves as a cushion. Accordingly, the lid 200, the lid locking mechanism 140, and other such constituent members are less likely to be subjected to unnecessary stress.

Furthermore, a substantially annular receiver 300c is provided to the edge of the opening 310. The receiver 300c protrudes from the second sealing face 300b. Providing the receiver 300c allows the second contact portion 204b to be securely and snugly brought into contact with the second sealing face 300b. Also, a substantially annular inclined face 300f that is adjacent to and touches the first sealing face 300a is formed at the outer peripheral part of the receiver 300c. The inclined face 300f is inclined toward the second sealing face 300b. Because of the inclined face 300f, the second contact portion 204b is guided to the second sealing face 300b side in closing the lid 200, and the second contact portion 204b more readily undergoes elastic deformation so as to move away from the opening 310.

Furthermore, a sealing groove 300g (an example of a concave portion) is formed by the first sealing face 300a, the second sealing face 300b, and the receiver 300c. The sealing groove 300g is disposed so as to surround the opening 310. When the lid 200 is in the closed state, the first contact portion 204a and the second contact portion 204b are accommodated in the sealing groove 300g. This sealing groove 300g makes it less likely that water will run into the holding unit 320 when the lid 200 has been opened.

Also, a protrusion 204e is provided to the waterproof gasket 204. When the lid 200 is in the closed state, the protrusion 204e pushes on a lid detection switch 305 provided inside the holding unit 320. Consequently, the power is prevented from being switched on if the lid 200 has not be properly closed, or access to the memory card 302 is halted and preparation for shutting off the power is begun if the lid 200 has been opened.

Furthermore, an attachment hole 204h is provided to the waterproof gasket 204 in order to attach a hinge 207 to the lid 200. An annular protrusion 204g that protrudes from the base portion 204c to the lid 200 side is formed at the peripheral part of the attachment hole 204h. When the waterproof gasket 204 is mounted to the lid 200 with the hinge 207, the annular protrusion 204g is pressed against the lid 200. Accordingly, attachment strength can be increased in attaching the waterproof gasket 204 to the lid 200.

Opening and Closing the Lid

Next, the operation in opening the lid 200 will be described. FIGS. 2A to 2D show the operation of the lid 200 from the closed state to an open state in time series. In FIGS. 2A to 2D, the digital camera 100 is upside-down.

In the state shown in FIG. 2A, the lock pawl 201a of the first lock lever 201 is hooked on the protrusion 303 (see FIG. 5). Also, the distal end of the leaf spring 205 is held by the second lock lever 202 in the restricting position, in which it is in contact with the first lock lever 201 (see FIG. 5). In this state, the first lock lever 201 can not move in the C direction. Therefore, the lid 200 does not readily come open. When the second lock lever 202 is slid in the C direction in the state shown in FIG. 2A, the lid locking mechanism 140 is in the state shown in FIG. 2B.

In the state shown in FIG. 2B, the distal end of the leaf spring 205 is disposed at the retracted position at which it is pushed by the second lock lever 202 to the Z axis direction positive side and does not hit the first lock lever 201, so the first lock lever 201 can be slid in the C direction. In the state shown in FIG. 2B, since the first lock lever 201 has not yet been slid in the C direction, the lock pawl 201a of the first lock lever 201 is hooked to the protrusion 303. Therefore, the lid 200 does not open. When the first lock lever 201 is slid in the C direction in the state shown in FIG. 2B, the lid locking mechanism 140 is in the state shown in FIG. 2C.

In the state shown in FIG. 2C, since the lock pawl 201a of the first lock lever 201 is not hooked to the protrusion 303, the lid 200 can be opened as shown in FIG. 2D.

As shown in FIG. 2D, in a state in which the lid 200 is open, the holding unit 320 is exposed. The battery 301 and the memory card 302 are held in the holding unit 320. The battery 301 and the memory card 302 can be installed or removed by opening the lid 200.

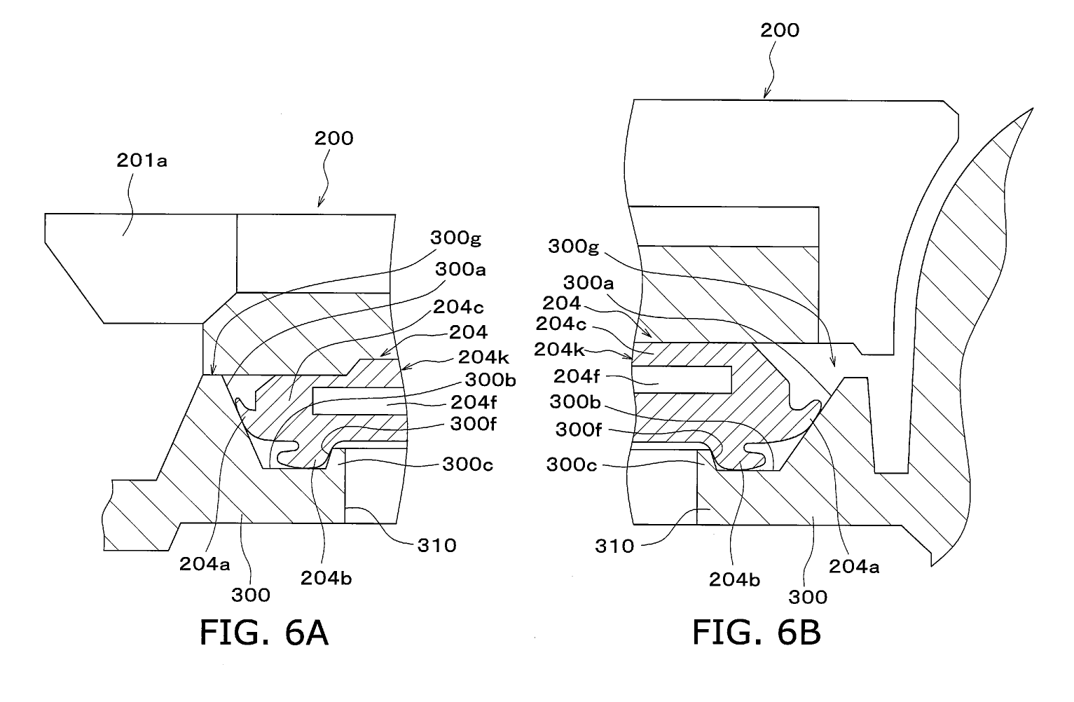

The operation for closing the lid 200 is the reverse of the operation for opening the lid 200. As shown in FIGS. 6A, 6B, 8A, and 8B, when the lid 200 is closed, the waterproof gasket 204 is pressed against the sealing portion 300. More specifically, the second contact portion 204b is pressed against the first sealing face 300a, and the second contact portion 204b is pressed against the second sealing face 300b. When the lid 200 is locked in the closed state by the lid locking mechanism 140, the waterproof gasket 204 is in the state shown in FIGS. 6A, 6B, 8A, and 8B, and the waterproof gasket 204 and the lid 200 put the holding unit 320 in a sealed state.

Features

The features of the digital camera 100 described above are compiled below.

(1) With the digital camera 100, since the waterproof gasket 204 has the first contact portion 204a and the second contact portion 204b, even if foreign matter should get stuck between the sealing portion 300 and the first contact portion 204a and create a gap, the sealing portion 300 and the second contact portion 204b can still prevent water from invading the holding unit 320. Also, even if foreign matter should get stuck between the sealing portion 300 and the second contact portion 204b and create a gap, the sealing portion 300 and the first contact portion 204a can still prevent water from invading the holding unit 320.

Thus, with the above constitution, sealing performance can be improved with a simple configuration.

(2) Since the first sealing face 300a is inclined so that it moves closer to the second sealing face 300b as it approaches the opening 310, when the lid 200 is closed the first contact portion 204a gradually is pressed against the first sealing face 300a. Therefore, it is easier to obtain a tighter fit between the first contact portion 204a and the first sealing face 300a.

(3) In a state in which the first contact portion 204a is pressed against the first sealing face 300a, the first contact portion 204a is elastically deformed so as to move away from the opening 310, so the first contact portion 204a undergoes elastic deformation toward the outside of the sealed region. Accordingly, the first contact portion 204a is pressed against the first sealing face 300a by external pressure, and the sealing with the first contact portion 204a is enhanced.

Also, in a state in which the first contact portion 204a is pressed against the first sealing face 300a, the first contact portion 204a is elastically deformed so as to move away from the second contact portion 204b, so the first contact portion 204a and the second contact portion 204b do not interfere with each other, and the elastic deformation of the first contact portion 204a and the second contact portion 204b is not hindered. Specifically, sealing performance of both the first contact portion 204a and the second contact portion 204b can be ensured.

(4) In a state in which the second contact portion 204b is pressed against the second sealing face 300b, the second contact portion 204b is elastically deformed so as to move away from the opening 310, so the second contact portion 204b undergoes elastic deformation toward the outside of the sealed region. Accordingly, the second contact portion 204b is pressed against the second sealing face 300b by external pressure, and the sealing with the second contact portion 204b is enhanced.

(5) In a state in which the first contact portion 204a is in contact with the first sealing face 300a, and the second contact portion 204b is in contact with the second sealing face 300b, a space S is formed between the first contact portion 204a and the second contact portion 204b. Therefore, the first contact portion 204a and the second contact portion 204b do not interfere with each other, and the elastic deformation of the first contact portion 204a and the second contact portion 204b is not hindered. Specifically, sealing performance of both the first contact portion 204a and the second contact portion 204b can be ensured.

Also, any foreign matter that has passed between the first contact portion 204a and the first sealing face 300a can be kept in the space S, so there can be anticipated an additional effect whereby this foreign matter is less likely to become trapped between the second contact portion 204b and the second sealing face 300b.

### Other Embodiments

The present invention is not limited to the embodiments given above, and various changes and modifications are possible without departing from the scope of the invention.

In the following description, those components having substantially the same function as in the above embodiments will be numbered the same, and will not be described again in detail.

(1) In the above embodiments, a lid sealing structure was described using the digital camera 100 as an example, but the lid sealing structure described above can also be applied to other devices, and not just to electronic devices such as the digital camera 100. For instance, the lid sealing structure described above can be used in a waterproof case that houses an electronic device (such as a marine case for a digital camera).

Also, the housing was described using the body 120 as an example in the above embodiments, but the constitution of the housing is not limited to that of the body 120. For instance, the housing need not have the holding unit 320, and may just have the sealing portion sealing portion 300 that forms the opening 310, for example.

(2) In the above embodiments, a waterproof gasket was described using the waterproof gasket 204 as an example, but the constitution of the waterproof gasket is not limited to that of the waterproof gasket 204. For instance, the waterproof gasket 204 may have other contact portions besides the first contact portion 204a and the second contact portion 204b.

Also, in the above embodiments, the first contact portion 204a protrudes outward from the base portion 204c, but the direction in which the first contact portion protrudes is not limited to the above-mentioned direction. Similarly, the direction in which the second contact portion 204b protrudes from the base portion 204c is not limited to the above-mentioned direction. Furthermore, the direction in which the second contact portion 204b protrudes is different from the direction in which the first contact portion 204a protrudes, but the directions in which the first contact portion 204a and second contact portion 204b protrude may instead be the same.

Further, the layouts of the first contact portion 204a and the second contact portion 204b may be switched around with each other.

(3) In the above embodiments, the sealing portion was described using the sealing portion 300 as an example, but the constitution of the sealing portion is not limited to that of the sealing portion 300. For instance, the sealing portion 300 has the first sealing face 300a and the second sealing face 300b, but it is also conceivable that the sealing portion 300 will have only the first sealing face 300a. In this case, the first contact portion 204a and second contact portion 204b may be disposed so as to be in snug contact with the first sealing face 300a.

It is also conceivable that the sealing portion 300 will have only the second sealing face 300b. In this case, the first contact portion 204a and second contact portion 204b may be disposed so as to be in snug contact with the second sealing face 300b.

(4) In the above embodiments, the second sealing face 300b is disposed closer to the opening 310 than the first sealing face 300a, but the second sealing face 300b may be disposed at a position that is farther from the opening 310 than the first sealing face 300a. That is, the layouts of the first sealing face 300a and the second sealing face 300b may be switched around.

Also, the first sealing face 300a is inclined with respect to the second sealing face 300b, but the first sealing face 300a may be disposed parallel to the second sealing face 300b, without being inclined with respect to the second sealing face 300b. Also, the first sealing face 300a is inclined with respect to the D direction, but the first sealing face 300a may be disposed parallel to the D direction (that is, perpendicular to the second sealing face 300b). Furthermore, the first sealing face 300a is inclined toward the opening 310, but the first sealing face 300a may be inclined in a different direction from that in the above constitution.

(5) In the above embodiments, the sealing groove 300g is formed by the first sealing face 300a and the second sealing face 300b, but the sealing portion 300 need not have a concave portion such as the sealing groove 300g. Also, the constitution of the concave portion is not limited to that of the sealing groove 300g.

### GENERAL INTERPRETATION OF TERMS

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiment(s), the following directional terms “forward”, “rearward”, “above”, “downward”, “vertical”, “horizontal”, “below” and “transverse” as well as any other similar directional terms refer to those directions of an electronic device. Accordingly, these terms, as utilized to describe the present invention should be interpreted relative to an electronic device.

The term “configured” as used herein to describe a component, section, or part of a device implies the existence of other unclaimed or unmentioned components, sections, members or parts of the device to carry out a desired function.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. A lid sealing structure comprising:
a housing defining an interior space with an opening, the housing includes a sealing portion that encircles the opening and provides access to the interior space;
a lid configured to cover and uncover the opening; and
a waterproof gasket including a base portion, a first contact portion and a second contact portion, the base portion being mounted to the lid, and the first and second contact portions extending from the base portion and arranged to contact the sealing portion.

2. The lid sealing structure according to claim 1, wherein
the sealing portion includes a first sealing surface configured to firmly contact the first contact portion and a second sealing surface configured to firmly contact the second contact portion.

3. The lid sealing structure according to claim 2, wherein
the second sealing surface is positioned closer to the opening than the first sealing surface.

4. The lid sealing structure according to claim 2, wherein
the first sealing surface is inclined at an angle relative to the second sealing surface.

5. The lid sealing structure according to claim 4, wherein
the first sealing surface is formed sloping away from the opening so as to encircle the first contact portion when the opening is covered by the lid.

6. The lid sealing structure according to claim 2, wherein
the housing further includes a concave portion defined by the first sealing surface and the second sealing surface to accommodate the first contact portion and the second contact portion.

7. The lid sealing structure according to claims 2, wherein
the lid is a substantially flat member that has a main surface, and
the second sealing surface is disposed substantially parallel to the main surface when the opening is covered by the lid.

8. The lid sealing structure according to claim 7, wherein
the first sealing surface is inclined at an angle relative to the main face of the lid, the angle of inclination of the first sealing surface is different from an angle of inclination of the second sealing surface formed relative to the main face of the lid.

9. The lid sealing structure according to claim 2, wherein
the first contact portion is elastically deflected away from the second sealing surface and the interior space of the housing when pressed against the first sealing surface.

10. The lid sealing structure according to claim 2, wherein
the first contact portion is elastically deflected away from the second contact portion and the interior space of the housing when pressed against the first sealing surface.

11. The lid sealing structure according to claim 2, wherein
the second contact portion is elastically deflected away from the opening and towards the first sealing surface when pressed against the second sealing surface.

12. The lid sealing structure according to claim 2, wherein
the lid is a substantially flat member that has a main surface, and
the first contact portion extends outwardly from the base portion and is disposed substantially parallel to the main surface, and the second contact portion extends outwardly from the base portion and is disposed at angle relative to the main surface.

13. The lid sealing structure according to claim 2, wherein
a space is formed between the first contact portion and the second contact portion when the first contact portion is in contact with the first sealing surface and the second contact portion is in contact with the second sealing surface.

14. The lid sealing structure according to claim 2, wherein
the housing further includes a receiver that encircles the opening and extends away from the second sealing surface.

15. The lid sealing structure according to claim 1, wherein
the second contact portion extends from the base portion in a direction different from the first contact portion.

16. The lid sealing structure according to claim 1, wherein
the second contact portion is positioned closer to the opening than the first contact portion when the opening is covered by the lid.

17. The lid sealing structure according to claim 1, wherein
the housing further includes a holding unit disposed inside the interior space of the housing and configured to hold accessories.

18. The lid sealing structure according to claim 1, wherein
the waterproof gasket is constructed of rubber, and the base portion is integrally formed with the first and second contact portions as a one-piece, unitary member.

19. The lid sealing structure according to claim 2, wherein
the lid is pivotally coupled to the housing, and the sealing portion is fixedly coupled to the housing.

20. An electronic device comprising the lid sealing structure according to claim 1.
